(19) United States
(12) Patent Application Publication
(10) Pub. No.: US 2026/0053042 A1
(43) Pub. Date: Feb. 19, 2026

(54) SEMICONDUCTOR PACKAGE AND OPERATING METHOD THEREOF

(71) Applicant: SAMSUNG ELECTRONICS CO., LTD., SUWON-SI (KR)

(72) Inventor: Hyung-Sun JANG, Suwon-si (KR)

(21) Appl. No.: 19/078,485

(22) Filed: Mar. 13, 2025

(30) Foreign Application Priority Data
Aug. 19, 2024 (KR) 10-2024-0110641

(51) Int. Cl. H01L 23/00

(52) U.S. Cl. CPC H01L 24/05; H01L 24/02; H01L 24/03; H01L 24/04; H01L 24/11; H01L 24/13; H01L 2224/0235; H01L 2224/02373; H01L 2224/0346; H01L 2224/0347; H01L 2224/0401; H01L 2224/05008; H01L 2224/05024; H01L 2224/05082; H01L 2224/11334; H01L 2224/13006

(57) ABSTRACT

A semiconductor package including: a semiconductor package comprising a first semiconductor chip which includes a first face and a second face opposite to each other in a first direction, a first insulating layer which is disposed on the first face, and includes vias connected to each connecting pad of the first semiconductor chip, redistribution patterns which are disposed on the first insulating layer, under bump metal layers (UBM) which are respectively disposed on the redistribution patterns, a second insulating layer which covers a part of each of the redistribution patterns, and solder bumps which are respectively disposed on the UBMs, wherein the first insulating layer includes a third face and a fourth face opposite to the third face in the first direction, wherein the third face is adjacent to the first face, and a part of the fourth face does not overlap the second insulating layer in the first direction.

### CROSS-REFERENCE TO RELATED APPLICATION

This application claims priority under 35 U.S.C. § 119 to Korean Patent Application No. 10-2024-0110641 filed on Aug. 19, 2024, in the Korean Intellectual Property Office, the disclosure of which is incorporated by reference herein in its entirety.

### 1. Technical Field

The present disclosure relates to a semiconductor package and a method for manufacturing the same.

### 2. Description of the Related Art

The growing development of the electronics industry has led to increasing demands for electronic components that offer high functionality, high speed, and small size. In line with this trend, wafer-level packaging, which involves reducing wafer thickness, has become widely adopted. However, grinding the back side of a wafer to achieve a thinner profile may result in defects caused by wafer warpage. This warpage can be exacerbated by differences in the thermal expansion coefficients of the layers comprising the wafer-level package.

### SUMMARY

Embodiments of the present disclosure provide a semiconductor package designed to minimize the occurrence of warpage-related defects.

Embodiments of the present disclosure also provide a method for manufacturing a semiconductor package designed to minimize the occurrence of warpage-related defects.

However, the embodiments of the present disclosure are not limited to those described herein. Additional features of the present disclosure will become apparent to those of ordinary skill in the upon reviewing the detailed description provided below.

According to an embodiment of the present disclosure, there is provided a semiconductor package comprising a first semiconductor chip which includes a first face and a second face opposite to each other in a first direction, a first insulating layer which is disposed on the first face, and includes vias connected to each connecting pad of the first semiconductor chip, redistribution patterns which are disposed on the first insulating layer, under bump metal layers (UBM) which are respectively disposed on the redistribution patterns, a second insulating layer which covers a part of each of the redistribution patterns, and solder bumps which are respectively disposed on the UBMs, wherein the first insulating layer includes a third face and a fourth face opposite to the third face in the first direction, wherein the third face is adjacent to the first face, and a part of the fourth face does not overlap the second insulating layer in the first direction.

According to an embodiment of the present disclosure, there is provided a semiconductor package comprising, a first semiconductor chip which includes a first face and a second face opposite to each other in a first direction, a first insulating layer which covers the first face, and includes a third face and a fourth face opposite to the third face in the first direction, wherein the third face is adjacent to the first face, first and second redistribution patterns on the first insulating layer, first and second under bump layers (UBM) on the first and second redistribution patterns, respectively, first and second solder bumps on the first and second UBMs, respectively, a first sub-insulating pattern on the fourth face and corresponding to the first redistribution pattern, and a second sub-insulating pattern on the fourth face and corresponding to the second redistribution pattern, wherein the first sub-insulating pattern covers at least a part of the first redistribution pattern, the second sub-insulating pattern covers at least a part of the second redistribution pattern, the first sub-insulating pattern and the second sub-insulating pattern are spaced apart from each other, and a first potion of the fourth face that does not overlap the first sub-insulating pattern in the first direction, and a second portion of the fourth face that does not overlap the second sub-insulating pattern in the first direction are exposed by the first sub-insulating pattern and the second sub-insulating pattern.

According to an embodiment of the present disclosure, there is provided a method for manufacturing a semiconductor package, the method comprising providing a semiconductor wafer on which a semiconductor chip is formed, the semiconductor chip including a first face on which connecting pads are disposed, and a second face opposite to the first face in a first direction, forming a first insulating layer which includes openings for exposing the connecting pads on the first face, and includes a third face facing the semiconductor chip, and a fourth face opposite to the third face in the first direction, forming vias connected to the connecting pads through the openings, simultaneously forming redistribution patterns connected to the vias on the first insulating layer, forming a second insulating layer which covers at least a part of each of the redistribution patterns on the first insulating layer, forming under bump metal layers (UBM) respectively corresponding to the redistribution patterns on the redistribution patterns, and forming solder bumps respectively corresponding to the UBMs on the UBMs, wherein at least a part of the fourth face does not overlap the second insulating layer in the first direction.

### BRIEF DESCRIPTION OF THE DRAWINGS

The above and other features of the present disclosure will become more apparent by describing in detail example embodiments thereof with reference to the attached drawings, in which:

FIG. 1 is a diagram for explaining a semiconductor package according to some embodiments.

FIG. 2 is a diagram schematically showing a partial configuration of the semiconductor package of FIG. 1.

FIG. 3 is a diagram for explaining a semiconductor package according to some embodiments.

FIG. 4 is a diagram that schematically shows a partial configuration of the semiconductor package of FIG. 2.

FIG. 5 is a diagram for explaining a semiconductor package according to some embodiments.

FIG. 6 is a diagram for explaining a semiconductor package according to some embodiments.

FIG. 7 is a cross-sectional view of a semiconductor package module including a semiconductor package according to some embodiments.

FIG. 8 is a cross-sectional view of a semiconductor package module including a semiconductor package according to some embodiments.

FIG. 9 is a cross-sectional view of a semiconductor package module including a semiconductor package according to some embodiments.

FIG. 10 is a cross-sectional view of a semiconductor package module including a semiconductor package according to some embodiments.

FIG. 11 is a cross-sectional view of a semiconductor package module including a semiconductor package according to some embodiments.

FIG. 12 is a cross-sectional view of a semiconductor package module including the semiconductor package according to some embodiments.

FIG. 13 is a cross-sectional view illustrating an example where a semiconductor package according to some embodiments is mounted on a main board of an electronic device.

FIG. 14 is a cross-sectional view showing an example where the semiconductor package according to some embodiments is mounted on the main board of the electronic device.

FIG. 15 is a plane layout diagram of a semiconductor package according to some embodiments.

FIG. 16 is a flowchart for explaining a method for manufacturing a semiconductor package according to some embodiments.

FIGS. 17, 18, 19, 20, 21, 22, 23, 24, 25, 26, 27, 28, 29, 30, 31, 32, 33, 34 and 35 are intermediate stage diagrams for explaining a method for manufacturing a semiconductor package according to some embodiments.

FIG. 36 is a diagram for explaining the configuration of a semiconductor package according to some embodiments.

FIG. 37 is a diagram for explaining an electronic system including a semiconductor package according to some embodiments.

### DETAILED DESCRIPTION OF THE EMBODIMENTS

Hereinafter, a semiconductor package according to some embodiments and a manufacturing method thereof will be described referring to the attached drawings.

The present disclosure focuses on improving the reliability and manufacturing efficiency of wafer-level semiconductor packages by addressing issues related to warpage and residual stress. Warpage occurs due to the mismatch in thermal expansion coefficients between the semiconductor chip's silicon substrate, the lower passivation layer, and the upper passivation layer. Traditional designs apply a large upper passivation layer over the redistribution layer (RDL) and other chip areas, which exacerbates these mismatches during critical manufacturing processes such as back grinding and sawing. These processes generate uneven thicknesses across the wafer, leading to residual stress, chipping, and other defects.

To resolve these challenges, this disclosure introduces a method to optimize the structure of passivation layers. Specifically, it minimizes the area occupied by the upper passivation layer, ensuring it only surrounds the necessary regions of the RDL or wraps specific areas entirely. This design exposes portions of the lower passivation layer, reducing the impact of thermal mismatches. By selectively applying the upper passivation layer, the present disclosure significantly reduces warpage, improves stress distribution during wafer processing, and minimizes defects, thereby enhancing the overall performance and yield of semiconductor packages.

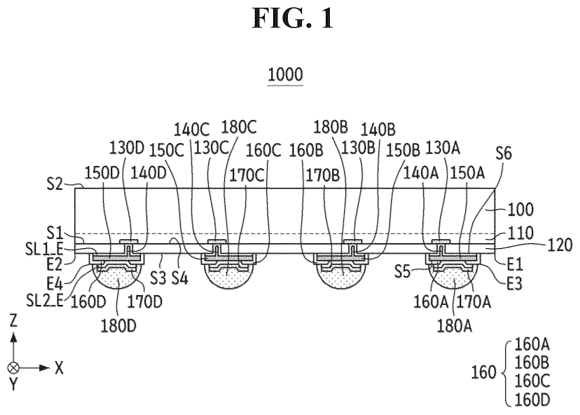

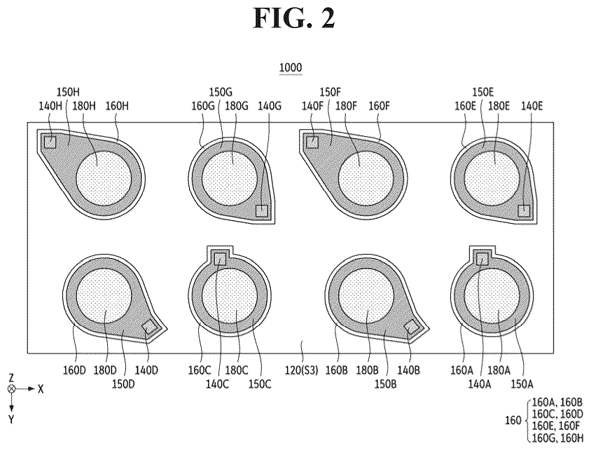

FIG. 1 is a diagram for explaining a semiconductor package according to some embodiments. FIG. 2 is a diagram schematically showing a partial configuration of the semiconductor package of FIG. 1.

Referring to FIGS. 1 and 2 together, a semiconductor package 1000 may include a semiconductor chip 100, a first insulating layer 120, redistribution patterns 150A to 150H, under bump metal layers (UBM) 170A to 170H, a second insulating layer 160, and solder bumps 180A to 180H. A plurality of connecting pads 130A to 130D may be provided in the semiconductor package 1000. The semiconductor package 1000 may be a fan-in wafer level package.

The semiconductor chip 100 may include a face S1 and a face S2 that are opposite to each other in a first direction Z. The face S1 may be a first face and the face S2 may be a second face. The faces S1 and S2 may also correspond to opposing sides of the semiconductor chip 100, for example first and second sides. The face S1 may be a lower face of the semiconductor chip 100, and the face S2 may be an upper face of the semiconductor chip 100. In the following description, an upward direction refers to the first direction Z, and a downward direction refers to the direction opposite to the first direction Z.

The semiconductor chip 100 may include a semiconductor element layer 110 positioned near the face S1. The semiconductor element layer 110 may be formed in a region of the semiconductor chip 100 adjacent to the redistribution patterns 150A to 150H. The semiconductor element layer 110 may include a plurality of individual elements of various types. For example, the plurality of individual elements may include various microelectronic components such as complementary metal-oxide semiconductor (CMOS) transistors, metal-oxide-semiconductor field effect transistors (MOSFETs), system large scale integration (LSI) components, image sensors like CMOS imaging sensors (CIS), micro-electro-mechanical systems (MEMS), active elements, passive elements, and the like.

The semiconductor chip 100 may include a logic semiconductor chip. The logic semiconductor chip may include, for example, a logic semiconductor chip such as a central processor unit (CPU), a micro processor unit (MPU), a graphic processor unit (GPU) or an application processor (AP). The semiconductor chip 100 may also include a memory semiconductor chip. The memory semiconductor chip may include, for example, a volatile memory semiconductor chip such as a dynamic random access memory (DRAM) or a static random access memory (SRAM), and may include a non-volatile memory semiconductor chip such as a phase-change random access memory (PRAM), a magneto-resistive random access memory (MRAM), a ferroelectric random access memory (FeRAM) or a resistive random access memory (RRAM).

The connecting pads 130A to 130D of the semiconductor chip 100 may be disposed on the face S1. The connecting pads 130A to 130D may be pads electrically connected to a plurality of individual elements inside the semiconductor element layer 110 of the semiconductor chip 100.

The connecting pads 130A to 130D may include aluminum (Al). However, the material of the connecting pads 130A to 130D may include metals such as nickel (Ni), copper (Cu), gold (Au), silver (Ag), tungsten (W), titanium (Ti), tantalum (Ta), indium (In), molybdenum (Mo), manganese (Mn), cobalt (Co), tin (Sn), magnesium (Mg), rhenium (Re), beryllium (Be), gallium (Ga), ruthenium (Ru), and alloys thereof, without being limited thereto.

The first insulating layer 120 may be disposed on the face S1 of the semiconductor chip 100. The first insulating layer 120 may include two opposing faces, S3 and S4, along the first direction Z, where face S4 is oriented toward face S1 of the semiconductor chip 100. In this case, the face S4 is in contact with the semiconductor chip 100. The first insulating layer 120 may cover the face S1 of the semiconductor chip 100 to protect the semiconductor chip 100. For example, as shown in FIG. 1, the first insulating layer 120 may be formed to entirely cover the face S1 of the semiconductor chip 100.

The first insulating layer 120 may be a layer of an insulating material, and may include an oxide or a nitride. For example, the first insulating layer 120 may include silicon oxide or silicon nitride. The first insulating layer 120 may also include an insulating material of a Photo Imageable Dielectric (PID) that can be subjected to a photolithography process. For example, the first insulating layer 120 may include a photosensitive polyimide (PSPI).

The first insulating layer 120 may include vias 140A to 140H. Upper ends of the vias 140A to 140H may be connected to the connecting pads 130A to 130D, and lower ends of the vias 140A to 140H may be connected to the redistribution patterns 150A to 150H. Each of the vias 140A to 140H may extend in the first direction Z. The vias 140A to 140H may electrically connect the connecting pads 130A to 130D and the redistribution patterns 150A to 150H. In some embodiments, the vias 140A to 140H may be formed by performing a plating process. The vias 140A to 140H may include metals such as nickel (Ni), copper (Cu), gold (Au), silver (Ag), tungsten (W), titanium (Ti), tantalum (Ta), indium (In), molybdenum (Mo), manganese (Mn), cobalt (Co), tin (Sn), magnesium (Mg), rhenium (Re), beryllium (Be), gallium (Ga), and ruthenium (Ru), or alloys thereof.

The redistribution patterns 150A to 150H may be positioned on the face S1 of the semiconductor chip 100 and on the face S3 of the first insulating layer 120. At least some of the redistribution patterns 150A to 150H may be disposed to be spaced apart from one other in a second direction X, which intersects the first direction Z. For example, the redistribution patterns 150A, 150B, 150C, and 150D may be spaced apart from each other in the second direction X. In addition, at least some of the redistribution patterns 150A to 150H may be spaced apart from one other in a third direction Y that intersects the first direction Z and the second direction X. For example, the redistribution patterns 150A and 150E, 150B and 150F, 150C and 150G, and 150D and 150H may be spaced apart from each other in the third direction Y.

The redistribution patterns 150A to 150H may consist of conductive material patterns that are electrically connected to the connecting pads 130A to 130D of the semiconductor chip 100. In some embodiments, the semiconductor package 1000 may further include a redistribution seed layer SL1_E interposed between each of the redistribution patterns 150A to 150H and the first insulating layer 120. The redistribution seed layer SL1_E may also be interposed between each of the vias 140A to 140D and the first insulating layer 120. In some embodiments, the redistribution seed layer SL1_E may be formed using a physical vapor deposition process, and the redistribution patterns 150A to 150H may be formed by using a plating process.

The redistribution patterns 150A to 150H may include copper (Cu). However, the material of the redistribution patterns 150A to 150H may be, but not limited to, metal such as nickel (Ni), gold (Au), silver (Ag), aluminum (Al), tungsten (W), titanium (Ti), tantalum (Ta), indium (In), molybdenum (Mo), manganese (Mn), cobalt (Co), tin (Sn), magnesium (Mg), rhenium (Re), beryllium (Be), gallium (Ga), ruthenium (Ru), or alloy thereof.

Hereinafter, the redistribution pattern 150A will be primarily described, with the understanding that the description applies equally to the other redistribution patterns 150B to 150H. The redistribution pattern 150A may include a face S5 and a face S6 that are opposite to each other in the first direction Z. The face S5 may be the lower face of the redistribution pattern 150A, and the face S6 may be the upper face of the redistribution pattern 150A. The face S6 of the redistribution pattern 150A may be oriented toward the semiconductor chip 100, and the face S5 of the redistribution pattern 150A may be oriented away from the semiconductor chip 100.

The second insulating layer 160 may be disposed on the face S3 of the first insulating layer 120. The second insulating layer 160 may include a plurality of sub-insulating patterns 160A to 160H. Each of the plurality of sub-insulating patterns 160A to 160H may cover at least a part of its corresponding redistribution pattern. For example, the sub-insulating pattern 160A may cover at least a part of the redistribution pattern 150A, the sub-insulating pattern 160B may cover at least a part of the redistribution pattern 150B, the sub-insulating pattern 160C may cover at least a part of the redistribution pattern 150C, and the sub-insulating pattern 160D may cover at least a part of the redistribution pattern 150D.

At least some of the sub-insulating patterns 160A to 160H may be spaced apart from one another in the second direction X. For example, the first to fourth sub-insulating patterns 160A, 160B, 160C, and 160D may be arranged with a spacing between them in the second direction X. At least some of the sub-insulating patterns 160A to 160H may also be spaced apart in the third direction Y. For example, the sub-insulating patterns 160A and 160E, 160B and 160F, 160C and 160G, and 160D and 160H, may each be spaced apart from one another in the third direction Y.

The sub-insulating pattern 160A will be primarily described below, with the understanding that the description equally applies to the sub-insulating patterns 160B to 160H. The sub-insulating pattern 160A may cover the outer face of the redistribution pattern 150A, and may cover at least a part of the face S5 of the redistribution pattern 150A. In other words, the sub-insulating pattern 160A may cover the outer surface of the redistribution pattern 150A and may extend over at least a portion of face S5 of the redistribution pattern 150A. At least a part of the face S5 of the redistribution pattern 150A may be exposed, without overlapping the sub-insulating pattern 160A, along the first direction Z. In other words, at least a part of the face S5 of the redistribution pattern 150A may not be in contact with the sub-insulating pattern 160A. At this point, the exposed part of face S5, for instance, the part not covered by the sub-insulating pattern 160A, may be covered by the UBM 170A.

Unlike the first insulating layer 120, which fully covers the face S4 of the semiconductor chip 100, the second insulating layer 160 may not completely cover the face S3 of the first insulating layer 120. In other words, portions of the face S3 of the first insulating layer 120 may remain exposed without overlapping the second insulating layer 160 along the first direction Z. For example, on the face S3 of the first insulating layer 120, a region between a first end E1 in the second direction X and the area where the sub-insulating pattern 160A is formed may remain exposed without overlapping the sub-insulating pattern 160A along the first direction Z. This selective exposure of portions of the first insulating layer 120 reduces thermal stress and minimizes warpage, enhancing the reliability and structural integrity of the semiconductor package. Similarly, the region on the face S3 between the area with sub-insulating pattern 160A and the area with sub-insulating pattern 160B may also remain exposed without overlapping sub-insulating patterns 160A and 160B in the first direction Z. Furthermore, the region between the area with sub-insulating pattern 160B and the area with sub-insulating pattern 160C on face S3 may likewise remain exposed without overlapping sub-insulating patterns 160B and 160C in the first direction Z.

In addition, on the face S3 of the first insulating layer 120, the region between the area with the sub-insulating pattern 160C and the area with the sub-insulating pattern 160D may remain exposed without overlapping the sub-insulating pattern 160C and the sub-insulating pattern 160D in the first direction Z. In addition, the region between a second end E2 in the second direction X and the area with the sub-insulating pattern 160D may remain exposed without overlapping the sub-insulating pattern 160D in the first direction Z.

The second insulating layer 160 may include a third end E3 and a fourth end E4 in the second direction X. The third end E3 may correspond to one end of the sub-insulating pattern 160A, located at the edge in the second direction X, among the sub-insulating patterns 160A to 160D included in the second insulating layer 160. Similarly, the fourth end E4 may correspond to one end of the sub-insulating pattern 160D, located at the edge in the direction opposite to the second direction X, among the sub-insulating patterns 160A to 160D included in the second insulating layer 160.

At this time, the third end E3 of the second insulating layer 160 may be positioned closer to the interior of the semiconductor chip 100 than the first end E1 of the first insulating layer 120. Similarly, the fourth end E4 of the second insulating layer 160 may be positioned closer to the interior of the semiconductor chip 100 than the second end E2 of the first insulating layer 120.

As illustrated in FIG. 2, the sub-insulating pattern 160A may be formed along an outline of the redistribution pattern 150A. Consequently, the regions on the face S3 of the first insulating layer 120 that do not overlap with the sub-insulating patterns 160A through 160H along the first direction Z may remain exposed between the sub-insulating patterns 160A through 160H.

The second insulating layer 160 may be a layer of an insulating material, and may include oxide or nitride. For example, the second insulating layer 160 may include silicon oxide or silicon nitride. The second insulating layer 160 may also include an insulating material of a PID. For example, the second insulating layer 160 may include photosensitive polyimide (PSPI).

UBMs 170A to 170H may be disposed on the redistribution patterns 150A to 150H, respectively. As shown in FIG. 1, the UBMs 170A to 170H may be disposed to correspond to each of the redistribution patterns 150A to 150H. The UBMs 170A to 170H may be configured to connect the redistribution patterns 150A to 150H and the solder bumps 180A to 180H. Hereinafter, a description will focus UBM 170A, with the understanding that the description of UBM 170A applies equally to the remaining UBMs 170B to 170H in the same manner.

In some embodiments, the semiconductor package 1000 may further include a UBM seed layer SL2_E interposed between the UBM 170A and the sub-insulating pattern 160A, and between the UBM 170A and the redistribution pattern 150A. In some embodiments, the UBM seed layer SL2_E may be formed using a physical vapor deposition process, and the UBM 170A may be formed through a plating process that utilizes the UBM seed layer SL2_E as a foundation.

The UBMs 170A to 170H may include, but are not limited to, metals such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), and ruthenium (Ru), or alloys thereof.

The solder bumps 180A to 180H may serve as conductive terminals positioned on each of the UBMs 170A to 170H and electrically connected to the connecting pads 130A to 130D of the semiconductor chip 100. For example, the solder bump 180A may cover at least a part of the lower face (or surface) of the sub-insulating pattern 160A, and may cover the outer face (or surface) of the UBM 170A. The solder bump 180A may establish electrical connections to a plurality of individual elements within the semiconductor element layer 110 of the semiconductor chip 100 through the UBM 170A, the redistribution pattern 150A, the via 140A, and the connecting pad 130A. In an example embodiment, the solder bumps 180A to 180H may be solder balls of a metal material that includes at least one of tin (Sn), silver (Ag), copper (Cu), and aluminum (Al).

During the manufacturing process of the semiconductor package 1000, differences in the Coefficients of Thermal Expansions (CTE) among the semiconductor chip 100, the first insulating layer 120, and the second insulating layer 160 may lead to warpage defects when back-grinding the face S2 of the semiconductor chip 100. In accordance with the present disclosure, the area of the second insulating layer 160, which serves to protect the redistribution pattern and the UBM, is minimized to mitigate warpage defects in the semiconductor chip 100.

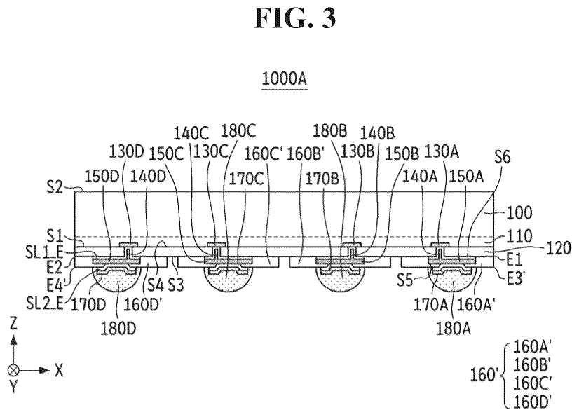

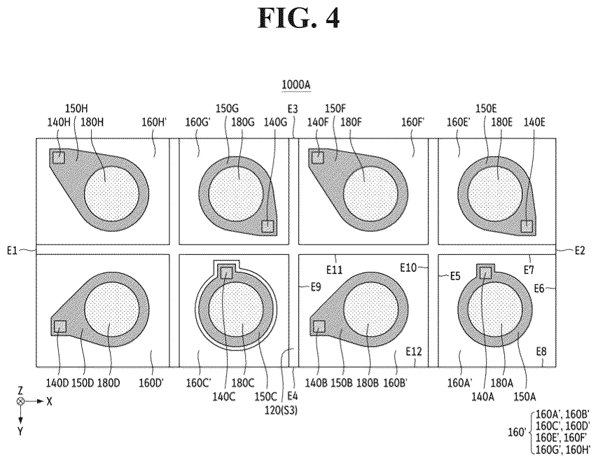

FIG. 3 is a diagram for explaining a semiconductor package according to some embodiments. FIG. 4 is a diagram that schematically shows a partial configuration of the semiconductor package of FIG. 2.

Hereinafter, repeated descriptions will be omitted and only differences will be addressed.

Referring to FIGS. 3 and 4 together, the semiconductor package 1000A may include a semiconductor chip 100, a first insulating layer 120, redistribution patterns 150A to 150H, UBMs 170A to 170H, a second insulating layer 160′, and solder bumps 180A to 180H. The second insulating layer 160′ may be disposed on the face S3 of the first insulating layer 120. The semiconductor package 1000A may be a fan-in wafer level package.

The second insulating layer 160′ may include a plurality of sub-insulating patterns 160A′ to 160H′. Each of the plurality of sub-insulating patterns 160A′ to 160H′ may cover at least a part of a corresponding redistribution pattern. For example, the sub-insulating pattern 160A′ may cover at least a part of the redistribution pattern 150A, the sub-insulating pattern 160B′ may cover at least a part of the redistribution pattern 150B, the pattern 160C′ may cover at least a part of the redistribution pattern 150C, and the sub-insulating pattern 160D′ may cover at least a part of the redistribution pattern 150D.

At least a part of the plurality of sub-insulating patterns 160A′ to 160H′ may be spaced apart from each other in the second direction X. For example, the sub-insulating patterns 160A′, 160B′, 160C′, and 160D′ may be spaced apart from one another in the second direction X. Furthermore, at least some of the plurality of sub-insulating patterns 160A′ to 160H′ may be spaced apart from one another in the third direction Y. For example, the sub-insulating patterns 160A′ and 160E′ may be spaced apart from each another in the third direction Y. Similarly, the sub-insulating patterns 160B′ and 160F′, 160C′ and 160G′, and 160D′ and 160H′ may also be spaced apart from each other in the third direction Y.

The following description will focus on the sub-insulating pattern 160A′, with the understanding that this description can be equally applied to the sub-insulating patterns 160B′ to 160H′. The sub-insulating pattern 160A′ may cover the outer face (or surface) of the redistribution pattern 150A and extend over at least a part of the face S5 of the redistribution pattern 150A. However, certain areas of the face S5 of the redistribution pattern 150A may remain uncovered, without making contact with the sub-insulating pattern 160A′.

Unlike the first insulating layer 120, which fully covers the face S1 of the semiconductor chip 100, the second insulating layer 160′ may not completely cover the face S3 of the first insulating layer 120. In other words, certain portions of the face S3 of the first insulating layer 120 may remain uncovered and exposed, as they do not overlap with the second insulating layer 160′ along the first direction Z.

Unlike the configuration shown in FIG. 1, where the region on the face S3 of the first insulating layer 120, between the first end E1 in the second direction X and the area with the sub-insulating pattern 160A does not come into contact with the sub-insulating pattern 160A, in this case, the region may come into contact with the sub-insulating pattern 160A′ and be covered by it. Similarly, unlike FIG. 1, where the region on the face S3 of the first insulating layer 120 between the second end E2 in the second direction X and the area with the sub-insulating pattern 160D does not come into contact with the sub-insulating pattern 160D, the region may come into contact with the sub-insulating pattern 160D′ and be covered by it.

The second insulating layer 160′ may include a third end E3′ and a fourth end E4′ in the second direction X. The third end E3′ may represent one end of the sub-insulating pattern 160A′, located at the edge in the second direction X among the sub-insulating patterns 160A′ through 160D′ included in the second insulating layer 160′. Similarly, the fourth end E4′ may represent one end of the sub-insulating pattern 160D′, located at the edge in the direction opposite to the second direction X among the sub-insulating patterns 160A′ through 160D′ included in the second insulating layer 160′.

At this time, the third end E3′ of the second insulating layer 160′ may overlap the first end E1 of the first insulating layer 120 in the first direction Z. Similarly, the fourth end E4′ of the second insulating layer 160 may overlap the second end E2′ of the first insulating layer 120 in the first direction Z.

Referring to FIG. 4, the face S3 of the second insulating layer 160 may include edges E1 and E2 extending in the third direction Y, and may include edges E3 and E4 extending in the second direction X. The edges E1 and E2 may be spaced apart from each other in the second direction X, and the edges E3 and E4 may be spaced apart from each other in the third direction Y.

The following description will focus on sub-insulating pattern 160A′ and sub-insulating pattern 160B′ as examples, with the understanding that the description applies equally to the remaining sub-insulating patterns 160C′ to 160H′ in the same manner. The sub-insulating pattern 160A′ may include edges E5 and E6 extending in the third direction Y, and edges E7 and E8 extending in the second direction X. The edges E5 and E6 may be spaced apart from each other in the second direction X, and the edges E7 and E8 may be spaced apart from each other in the third direction Y.

The sub-insulating pattern 160B′ may include edges E9 and E10 extending in the third direction Y, and edges E11 and E12 extending in the second direction X. The edges E9 and E10 may be spaced apart from each other in the second direction X, and the edges E11 and E12 may be spaced apart from each other in the third direction Y.

In some embodiments, the edges E2 and E6 may overlap each other in the third direction Y when viewed in a planar view. The edges E4 and E8 may overlap each other in the second direction X when viewed in a planar view, and the edges E4 and E12 may overlap each other in the second direction X when view in a planar view.

In this way, in some embodiments, unlike the arrangement shown in FIG. 2, where the sub-insulating patterns are disposed to follow the shape of the redistribution pattern, each sub-insulating pattern corresponds to a single redistribution pattern and may be arranged to surround the entire region occupied by the redistribution pattern. Accordingly, an area covered by the sub-insulating pattern may be larger than that in the embodiment shown in FIG. 2, and the regions where the face S3 of the first insulating layer 120 does not overlap the sub-insulating pattern in the first direction Z may be relatively small. This configuration can enhance the reliability of protection for the elements inside the semiconductor chip 100.

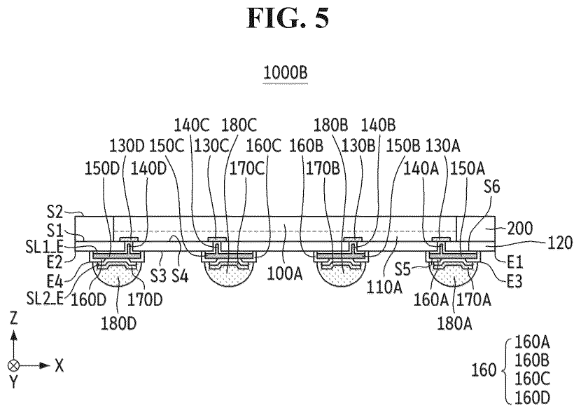

FIG. 5 is a diagram for explaining a semiconductor package according to some embodiments.

Referring to FIG. 5, a semiconductor package 1000B may include a semiconductor chip 100, a first insulating layer 120, redistribution patterns 150A to 150H, UBMs 170A to 170H, a second insulating layer 160, solder bumps 180A to 180H, and a mold layer 200. The semiconductor package 1000B may be a fan-out wafer level package.

The mold layer 200 may be a layer that surrounds the semiconductor chip 100 on the first insulating layer 120. The mold layer 200 may also function to secure the semiconductor chip 100 to the first insulating layer 120. In an example embodiment, the mold layer 200 may surround the side face of the semiconductor chip 100 on the first insulating layer 120. However, unlike that shown in FIG. 5, the mold layer 200 may also surround the side face of the semiconductor chip 100 and the face S2, which corresponds to the upper face of the semiconductor chip 100. The mold layer 200 may be made of an epoxy molding compound. However, the material of the mold layer 200 is not limited to an epoxy molding compound and may include various alternatives, for example, an epoxy-based material, a thermosetting material, a thermoplastic material, a UV-treated material, or the like.

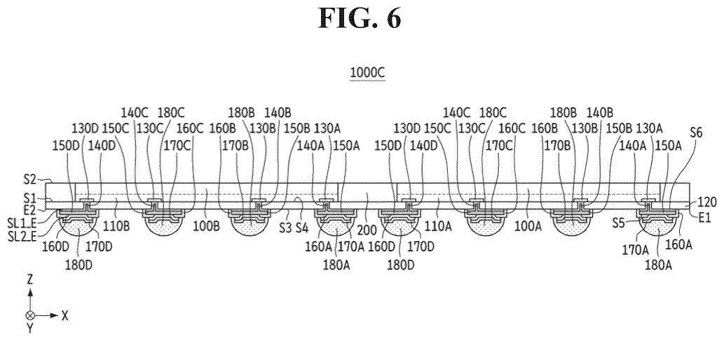

FIG. 6 is a diagram for explaining a semiconductor package according to some embodiments.

Referring to FIG. 6, a semiconductor package 1000C may include a semiconductor chip 100A, a semiconductor chip 100B, a first insulating layer 120, redistribution patterns 150A to 150H, UBMs 170A to 170H, a second insulating layer 160, solder bumps 180A to 180H, and a mold layer 200. The semiconductor package 1000C may be a fan-out wafer level package. The semiconductor chips 100A and 100B may include logic semiconductor chips or memory semiconductor chips. Each of the semiconductor chips 100A and 100B may include semiconductor element layers 110A and 110B on their respective lower faces. The description of the semiconductor chips 100A and 100B is the same as that of the semiconductor chip 100 (shown in FIG. 1), and therefore, will not be repeated here.

The mold layer 200 may be a layer that surrounds the semiconductor chip 100A and the semiconductor chip 100B on the first insulating layer 120. For example, the mold layer 200 may separate the semiconductor chip 100A from the semiconductor chip 100B. The mold layer 200 may also function to secure the semiconductor chip 100A and the semiconductor chip 100B to the first insulating layer 120. In an example embodiment, the mold layer 200 may surround the side faces of the semiconductor chip 100A and the semiconductor chip 100B on the first insulating layer 120. However, as shown in FIG. 6, the mold layer 200 may also extend to surround not only the side faces but also the upper faces of the semiconductor chips 100A and 100B.

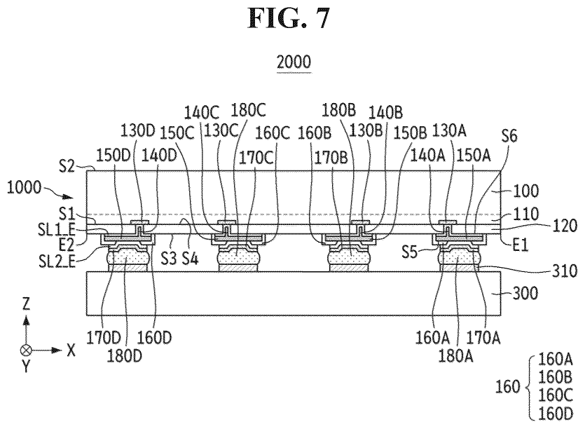

FIG. 7 is a cross-sectional view of a semiconductor package module including a semiconductor package according to some embodiments.

Referring to FIG. 7, the semiconductor package included in the semiconductor package module 2000 may correspond to the semiconductor package 1000 of FIG. 1. The semiconductor package module 2000 may be referred to as a semiconductor package. The semiconductor package module 2000 may include a circuit board 300 and a semiconductor package 1000. The circuit board 300 may be a printed circuit board. A connecting pad 310 may be located on the circuit board 300. The solder bumps 180A to 180H of the semiconductor package 200 may be connected to the connecting pads 310, respectively. The solder bumps 180A to 180H of the semiconductor package 1000 may be mechanically and electrically connected to the circuit board 300 through the connecting pads 310.

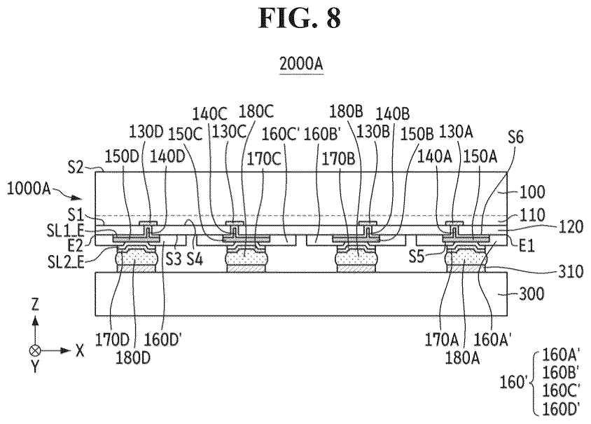

FIG. 8 is a cross-sectional view of a semiconductor package module including a semiconductor package according to some embodiments.

Referring to FIG. 8, the semiconductor package included in the semiconductor package module 2000A may correspond to the semiconductor package 1000A of FIG. 3. The semiconductor package module 2000A may be referred to as a semiconductor package. The semiconductor package module 2000A may include a circuit board 300 and a semiconductor package 1000A. The circuit board 300 may be a printed circuit board. The connecting pad 310 may be located on the circuit board 300. The solder bumps 180A to 180H of the semiconductor package 1000A may be connected to the connecting pads 310, respectively. The solder bumps 180A to 180H of the semiconductor package 1000A may be mechanically and electrically connected to the circuit board 300 through the connecting pads 310.

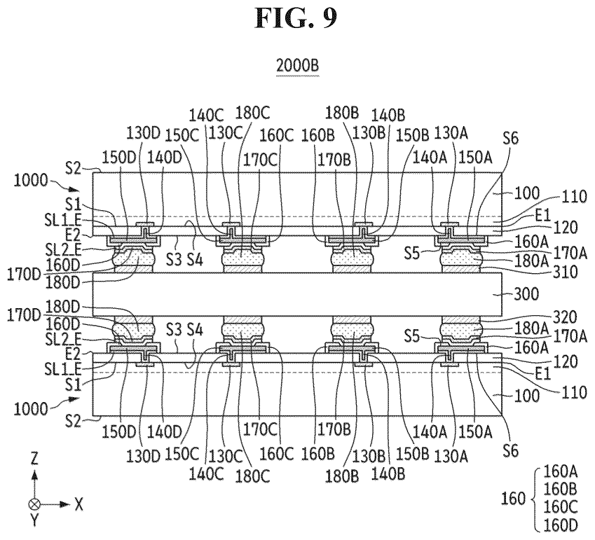

FIG. 9 is a cross-sectional view of a semiconductor package module including a semiconductor package according to some embodiments.

Referring to FIG. 9, semiconductor package module 2000B is similar to the semiconductor package module of FIG. 7, except that an upper semiconductor package 1000 and a lower semiconductor package 1000 are disposed on opposite faces of the circuit board 300. Each of the upper and lower semiconductor packages 1000 may correspond to the semiconductor package 1000 of FIG. 1.

The semiconductor package module 2000B may include the upper semiconductor package 1000, the lower semiconductor package 1000, the circuit board 300, and the connecting pads 310 and 320. The circuit board 300 may be a printed circuit board. Each of the upper connecting pad 310 and the lower connecting pad 320 may be positioned on the upper and lower faces of the circuit board 300, respectively. The solder bumps 180A to 180H of the upper semiconductor package 1000 may be connected to the upper connecting pad 310. The solder bumps 180A to 180H of the lower semiconductor package 1000 may be connected to the lower connecting pad 320. The solder bumps 180A to 180H of the upper and lower semiconductor packages 1000 may be mechanically and electrically connected to the circuit board 300 through the upper and lower connecting pads 310 and 320. The semiconductor package module 2000B, as described above, includes the upper and lower semiconductor packages 1000 on the upper and lower sides of the circuit board 300, respectively. This configuration may increase the overall capacity, such as memory capacity.

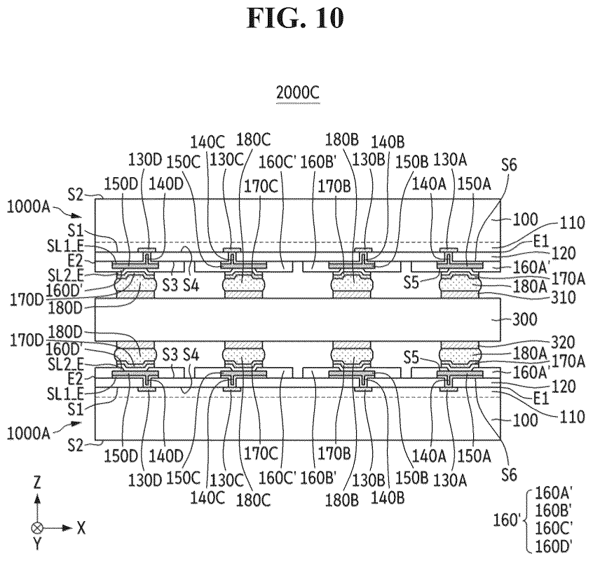

FIG. 10 is a cross-sectional view of a semiconductor package module including a semiconductor package according to some embodiments.

Referring to FIG. 10, unlike the semiconductor package module 2000B of FIG. 9, each of the upper semiconductor package 1000A and the lower semiconductor package 1000A of a semiconductor package module 2000C may correspond to the semiconductor package 1000A of FIG. 3.

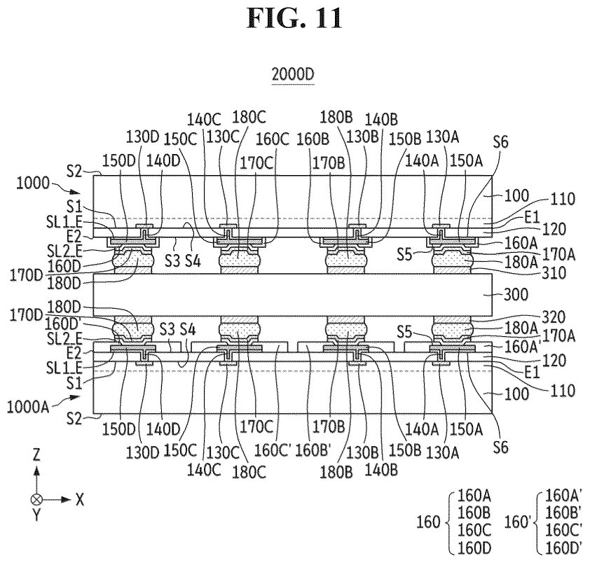

FIG. 11 is a cross-sectional view of a semiconductor package module including a semiconductor package according to some embodiments.

Referring to FIG. 11, unlike the semiconductor package module 2000B of FIG. 9 and the semiconductor package module 2000C of FIG. 10, semiconductor package module 2000D includes different semiconductor packages on the two sides of the circuit board 300. Specifically, the semiconductor package connected to the upper part of the circuit board 300 may correspond to the semiconductor package 1000 described in FIG. 1, while the semiconductor package connected to the lower part of the circuit board 300 may correspond to the semiconductor package 1000A described in FIG. 3.

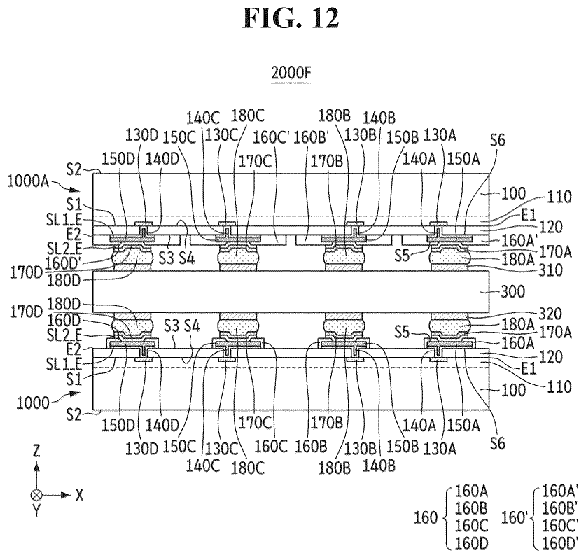

FIG. 12 is a cross-sectional view of a semiconductor package module including the semiconductor package according to some embodiments.

Referring to FIG. 12, unlike the semiconductor package module 2000D of FIG. 11, a semiconductor package module 2000F includes a different arrangement of semiconductor packages. In this configuration, the semiconductor package connected to the upper part of the circuit board 300 corresponds to the semiconductor package 1000A described in FIG. 3, while the semiconductor package connected to the lower part of the circuit board 300 corresponds to the semiconductor package 1000 described in FIG. 1.

In this way, when the semiconductor packages are connected to each of the upper and lower parts of the circuit board 300, the semiconductor packages having different sub-insulating pattern configurations may be used on the upper and lower parts of the circuit board 300.

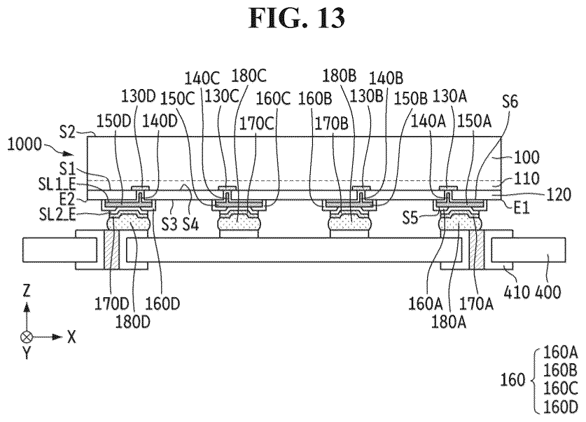

FIG. 13 is a cross-sectional view showing a case where a semiconductor package according to some embodiments is mounted on a main board of an electronic device.

Referring to FIG. 13, the semiconductor package 1000 may be mounted on the main board 400 of an electronic device through solder bumps 180A to 180H, and the mounted package and the main board 400 may form a wafer-level semiconductor package module. A terminal 410 may be located on the upper face of the main board 400, and the solder bumps 180A and 180D of the semiconductor package 1000 may be connected to the terminal 410. The semiconductor package mounted on the main board 400 may be the semiconductor package of FIG. 1. For example, the semiconductor package 1000 may be a fan-type semiconductor package.

This disclosure is applicable to a wafer-level semiconductor package that can be mounted directly onto the main board 400 of an electronic device without requiring a separate interposer substrate. Although the drawings illustrate only a fan-in wafer-level semiconductor package, the disclosure may also be applied to other types of wafer-level packages.

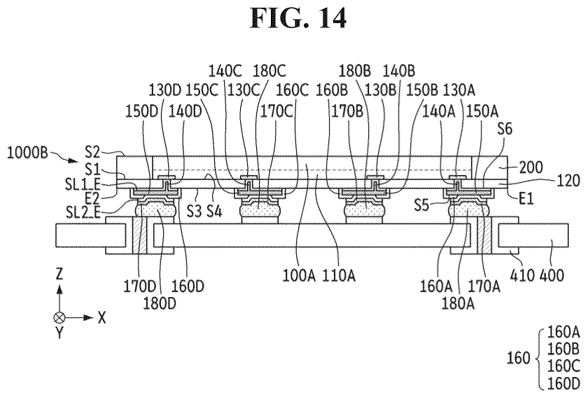

FIG. 14 is a cross-sectional view showing a schematic case in which the semiconductor package according to some embodiments is mounted on the main board of the electronic device.

Referring to FIG. 14, the semiconductor package 1000B may be mounted on the main board 400 of the electronic device through solder bumps 180A and 180D, and the like, and the mounted package and the main board 400 may form a wafer-level semiconductor package module. The terminal 410 may be located on the upper face of the main board 400, and the solder bumps 180A and 180D of the semiconductor package 1000B may be connected to the terminal 410. The semiconductor package mounted on the main board 400 may be the semiconductor package of FIG. 5. For example, the semiconductor package 1000B may be a fan-out semiconductor package. The present disclosure applies to a wafer-level semiconductor package that can be mounted directly onto the main board 400 of the electronic device without requiring a separate interposer substrate, or the like. While the drawings illustrate only a fan-out wafer-level semiconductor package, the disclosure may also be applicable to other types of wafer-level packages

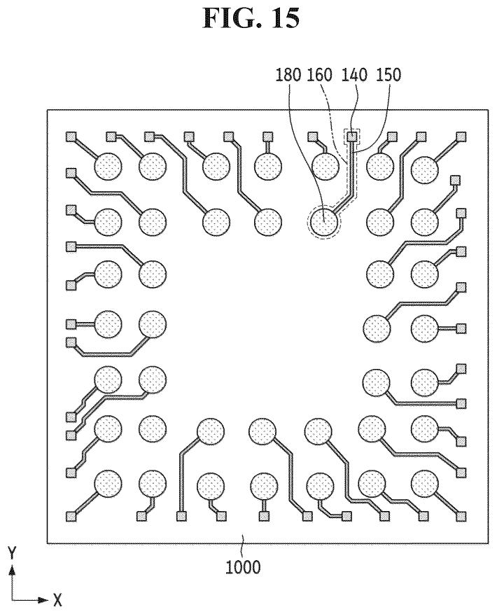

FIG. 15 is a plane layout diagram of a semiconductor package according to some embodiments.

FIG. 15 may be a diagram showing a planar layout of the semiconductor package of FIG. 1. Referring to FIG. 15, in the semiconductor package 1000, the redistribution patterns 150 may extend in the second direction X and/or the third direction Y, e.g., a horizontal direction. One end of the redistribution patterns 150 may be connected to the solder bumps 180, and the other end of the redistribution patterns 150 may be connected to the vias 140. At this time, the solder bumps 180 may be positioned in the central portion of the semiconductor package 1000, and the vias 140 may be positioned in the edge portion of the semiconductor package 1000. Each sub-insulating pattern 160 may be formed to surround the redistribution pattern 150, conforming to the shape of the redistribution pattern 150.

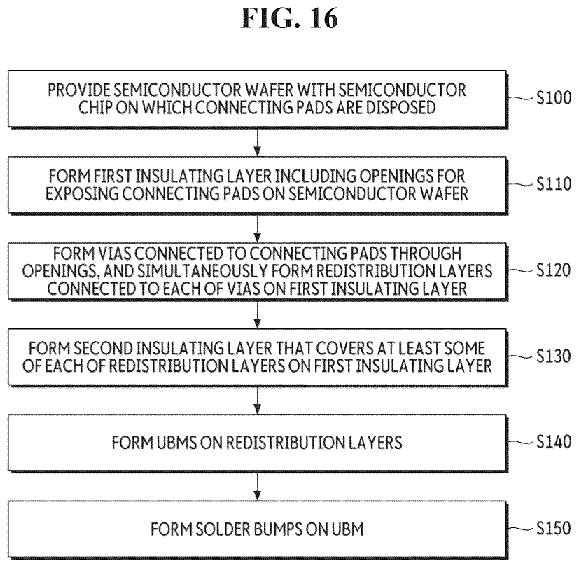

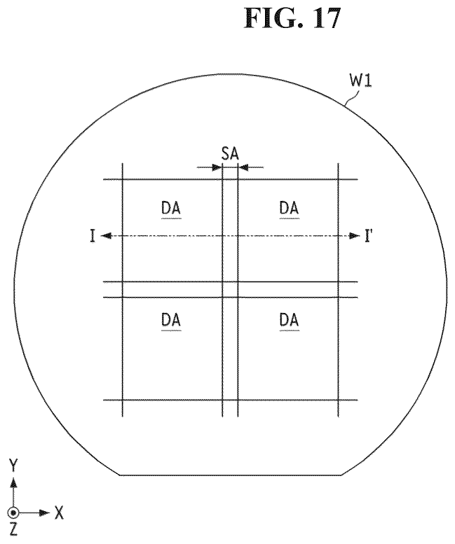

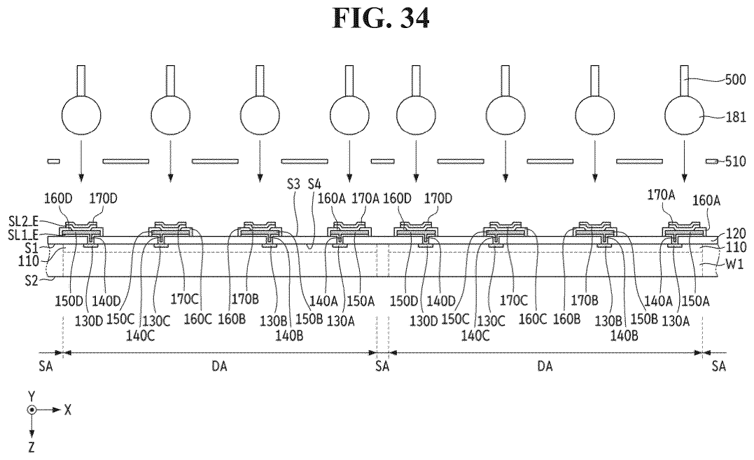

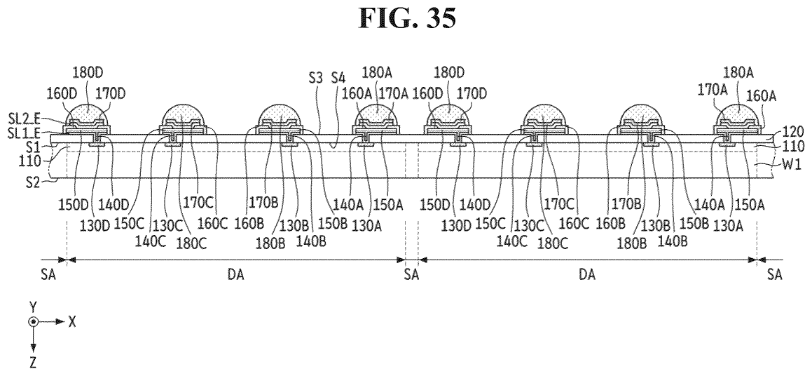

FIG. 16 is a flowchart for explaining a method for manufacturing a semiconductor package according to some embodiments. FIGS. 17 to 35 are intermediate stage diagrams for explaining a method for manufacturing a semiconductor package according to some embodiments.

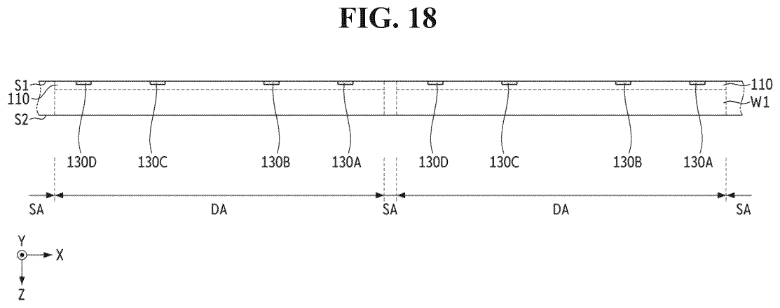

FIG. 17 is a plan view showing a semiconductor wafer on which a plurality of semiconductor chips are formed, and FIGS. 18 to 35 are cross-sectional views taken along I-I of FIG. 17. Hereinafter, the method for manufacturing a semiconductor package according to the embodiment of FIG. 1 will be described referring to FIGS. 16 to 35.

First, referring to FIGS. 16 to 18, a semiconductor wafer W1 having a plurality of semiconductor chips 100 formed thereon may be provided (S100). In other words, a semiconductor wafer W1, on which a plurality of semiconductor chips 100 are formed, may be provided. The semiconductor wafer W1 may include a substrate which has both faces opposite to each other in the first direction Z. In other words, the semiconductor wafer W1 may include a substrate with two opposing faces oriented along the first direction Z. The substrate may include a die region DA, and a scribe lane region SA that surrounds the die region DA. The substrate may be cut along the scribe lane region SA, which separates the plurality of die regions DA of the semiconductor wafer W1, through a subsequent sawing process. This process individualizes the substrate into a plurality of semiconductor chips.

Circuit elements may be formed in the die region DA on one face of the semiconductor wafer W1. For example, the circuit elements may include an integrated circuit for performing power source-related functions such as a power management semiconductor, a battery management, and a DC-DC converters.

The circuit element may include a plurality of memory elements. Examples of the memory element may include a volatile semiconductor memory element and a non-volatile semiconductor memory element. Examples of the volatile semiconductor memory element may include a DRAM, a SRAM, etc. Examples of the non-volatile semiconductor memory element may include an EPROM, an EEPROM, a Flash EEPROM, etc.

For example, the substrate may include semiconductor materials such as silicon, germanium, and silicon-germanium, or group III-V compound semiconductors such as gallium phosphide (GaP), gallium arsenide (GaAs), and gallium antimonide (GaSb). According to some embodiments, the substrate may be a silicon-on-insulator (SOI) substrate or a germanium-on-insulator (GOI) substrate.

The circuit elements may include, for example, a transistor, a capacitor, a wiring structure, and the like. The circuit elements may be formed on one of the two opposing faces of the substrate, oriented along the first direction Z, through a fabrication (Fab) process known as the front-end-of-line (FEOL) process for manufacturing semiconductor elements. The surface (or face) of the substrate on which the FEOL process is performed is referred to as a front side surface of the substrate, and a face opposite to the front side surface is referred to as a back side surface.

Connecting pads 130A to 130D may be disposed on the face S1 of the semiconductor chip 100. The connecting pads 130A to 130D may be spaced apart from each other in the second direction X. In addition, at least some of the connecting pads formed on the face S1 of the semiconductor chip 100 may be spaced apart from each other in the third direction Y.

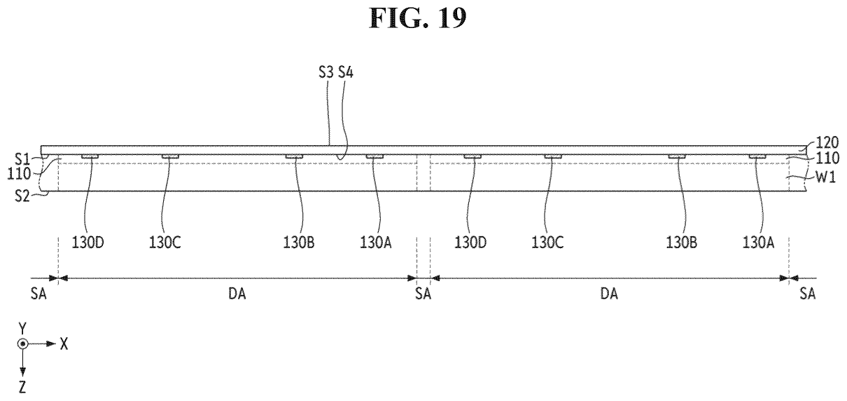

Next, referring to FIGS. 16 and 19 to 21, a first insulating layer 120 including openings OP1A that expose the connecting pads 130A to 130D may be formed on the semiconductor wafer W1 (S110). For example, referring to FIG. 19, the first insulating layer 120 may be disposed on the face of the semiconductor wafer W1 where the connecting pads 130A to 130D are formed. This face is one of the two opposing faces of the semiconductor wafer W1 along the first direction Z. At this time, the face S4 of the first insulating layer 120 may be oriented toward the face of the semiconductor wafer W1 on which the connecting pads 130A to 130D are formed. The first insulating layer 120 may be formed on the semiconductor wafer W1 by a spin coating process. However, the embodiment is not limited thereto, and the first insulating layer 120 may be formed on the semiconductor wafer W1 by a vapor phase deposition process.

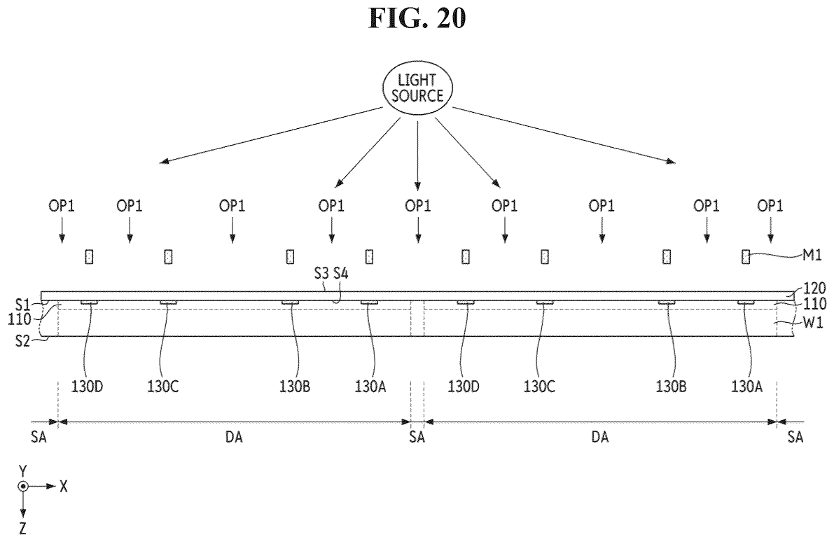

Next, referring to FIG. 20, a mask pattern M1 including the openings OP1 may be disposed on the first insulating layer 120, and the semiconductor wafer W1 on which the first insulating layer 120 is formed may be exposed to a light source with the mask pattern M1 sandwiched therebetween. At this time, as shown in FIG. 20, the mask pattern M1 may be spaced apart from the face S3 of the first insulating layer 120 in the direction opposite to the first direction Z. However, the embodiment is not limited thereto, and the mask pattern M1 may come into contact with the face S4 of the first insulating layer 120. When the exposure process is completed, a development process, a curing process, a descum process using plasma, and the like may then be performed.

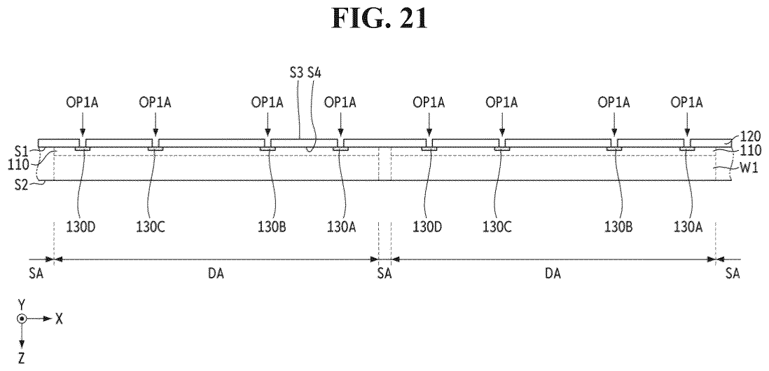

Next, referring to FIG. 21, when the descum process for removing residues using plasma is performed, openings OP1A may be formed in the first insulating layer 120. At this time, the openings OP1A may be formed on the first insulating layer 120 to be aligned with the openings OP1 of the mask pattern M1 in the first direction Z. The openings OP1A may be formed on the first insulating layer 120 to be spaced apart from each other in the second direction X, and each of the openings OP1A may extend in the first direction Z. At least a part of the lower face of the redistribution patterns 150A to 150H (shown in FIG. 1) may be exposed through the openings OP1A.

Referring to FIGS. 20 and 21 together, during the exposure process, regions of the first insulating layer 120 covered by the mask pattern M1 and not exposed to light may be dissolved by the developer. Conversely, regions of the first insulating layer 120 not covered by the mask pattern M1 and exposed to light during the exposure process may remain undissolved by the developer. In this way, the first insulating layer 120 may be a negative material.

Next, referring to FIGS. 16 and 22 to 25, vias 140A through 140D, which are connected to the connecting pads 130A through 130D via the openings OP1A, may be formed. Simultaneously, redistribution patterns 150A through 150D, each connected to one of the vias 140A through 140D, may be formed on the first insulating layer 102 (S120).

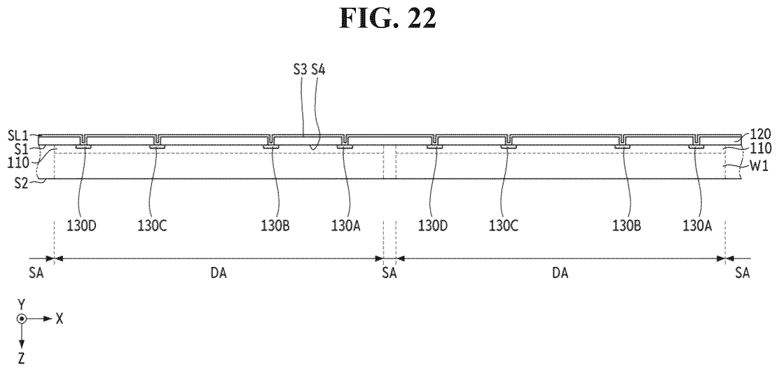

For example, referring to FIG. 22, a first seed film SL1 may be formed on the first insulating layer 120 and the connecting pads 130A to 130D inside the opening OP1A. The first seed film SL1 may be formed through a physical vapor deposition process, but is not limited thereto.

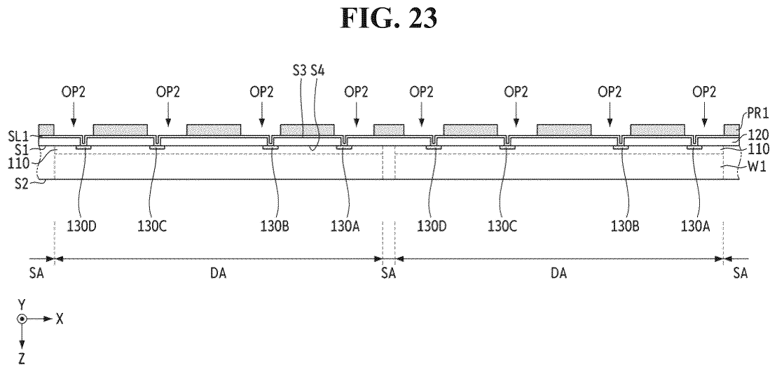

Next, referring to FIG. 23, a photoresist pattern PR1 including openings OP2 may be formed on the first insulating layer 120. At this time, the openings OP2 of the photoresist pattern PR1 may be formed by first applying a photoresist uniformly to the face S3 of the first insulating layer 120 using a spin coating method. Subsequently, an exposure and development process is performed using a mask to define the opening. In other words, the openings OP2 of the photoresist pattern PR1 may be formed by the pattern of the mask. The photoresist pattern PR1 may be formed to include the openings OP2 that have a width larger than the openings OP1A (shown in FIG. 21) in a region corresponding to the openings OP1A.

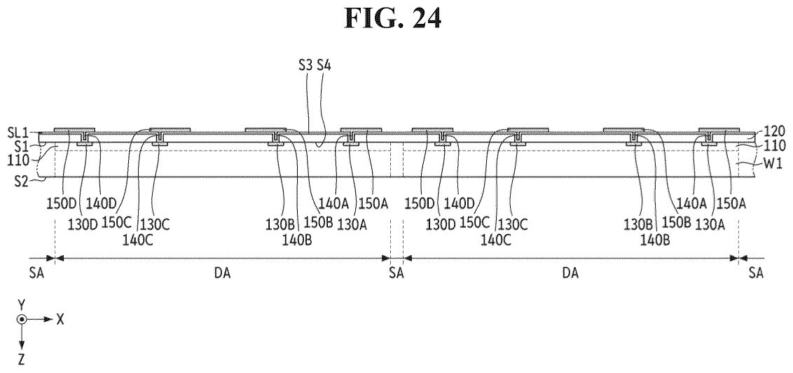

Next, referring to FIG. 24, the vias 140A to 140D and the redistribution patterns 150A to 150D may be simultaneously formed in each opening OP2 by a metal plating method, and the photoresist pattern PR1 may be removed. At this time, each of the vias 140A to 140D may fill the openings OP1A formed on the first insulating layer 120. The upper ends of each of the vias 140A to 140D may be connected to the exposed portions among the lower faces of each of the redistribution patterns 150A to 150D. The vias 140A to 140D and the redistribution patterns 150A to 150D may be formed by an electroless plating or electrolytic plating process.

However, in the present disclosure, the method of forming the vias 140A to 140D and the redistribution patterns 150A to 150D is not limited thereto, and the vias may be formed by forming a metal layer and patterning the metal layer through an etching process.

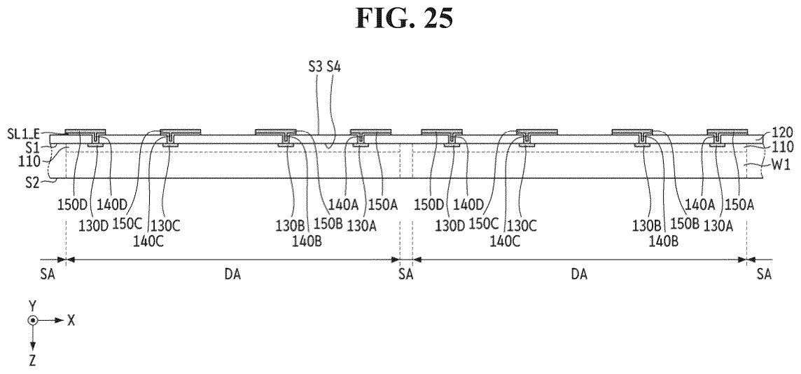

Next, referring to FIG. 25, the first seed film SL1 may be etched to form a redistribution seed layer SL1_E. The redistribution seed layer SL1_E may be interposed between the redistribution patterns 150A to 150H and the first insulating layer 120. At least a part of the first seed film SL1 that covers the face S3 of the first insulating layer 120 may be removed by etching the first seed film SL1.

Next, referring to FIGS. 16 and 26 to 28, a second insulating layer 160 that covers at least a part of each of the redistribution patterns 150A to 150D may be formed on the first insulating layer 120 (S130).

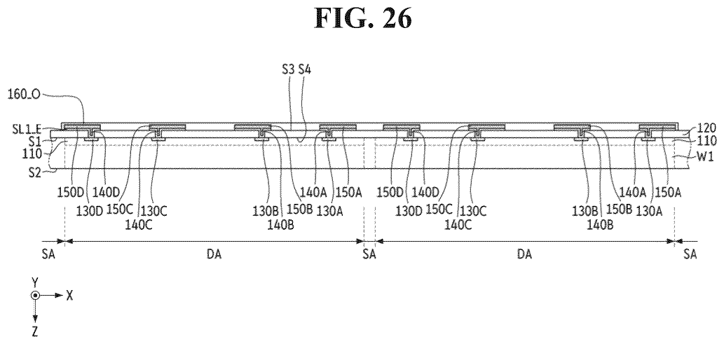

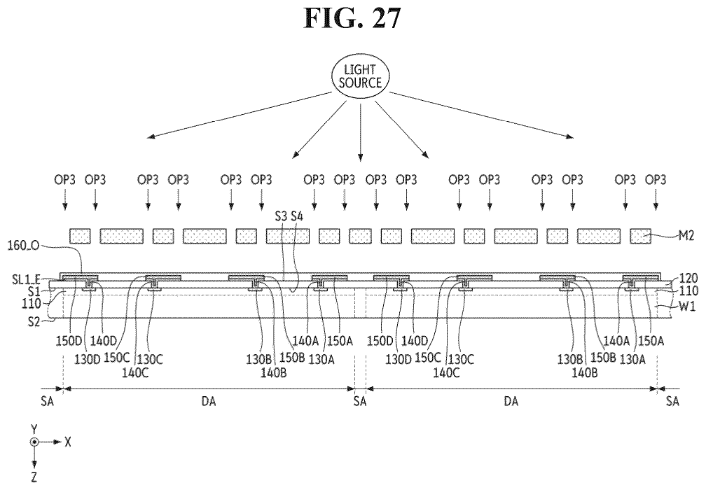

For example, first, referring to FIG. 26, a second original insulating layer 160_O that covers all the redistribution patterns 140A to 140D may be formed on the face S3 of the first insulating layer 120. Next, referring to FIG. 27, a mask pattern M2 including openings OP3 is disposed on the second original insulating layer 160_O. The semiconductor wafer W1, with the second original insulating layer 160_O formed on it, may then be exposed to a light source with the mask pattern M2 sandwiched therebetween. At this time, as shown in FIG. 27, the mask pattern M2 may be spaced apart from the second original insulating layer 160_O in the direction opposite to the first direction Z. However, this is not a limitation, and the mask pattern M2 may alternatively be positioned in direct contact with the lower face of the second original insulating layer 160_O. When the exposure process is completed, a development process, a curing process, a descum process using plasma, and the like may then be performed.

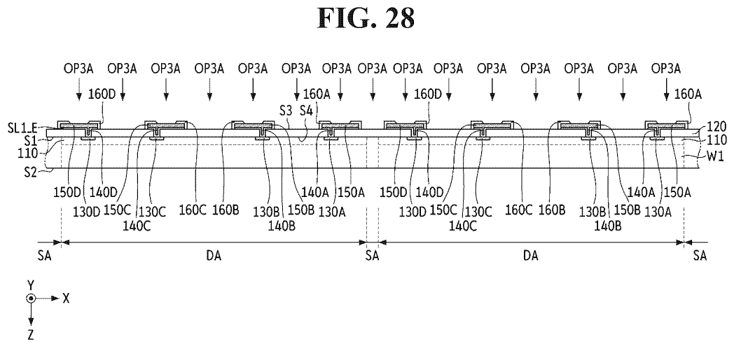

Next, referring to FIG. 28, when the descum process for removing residues using plasma is performed, openings OP3A may be formed on the second original insulating layer 160_O. As a result, a plurality of sub-insulating patterns 160A to 160D may be formed. At this time, the openings OP3A may be formed on the second original insulating layer 160_O in regions that do not overlap with the openings OP3 of the mask pattern M2 along the first direction Z during the exposure process of FIG. 27.

Referring again to FIG. 27, the portions of the second original insulating layer 160_O that are covered by the mask pattern M2 and not exposed to light during the exposure process may later be dissolved by a developer during the development process. Conversely, the portions of the second original insulating layer 160_O that are not covered by the mask pattern M2 and exposed to light during the exposure process may remain undissolved by the developer in the development process. In this way, the second original insulating layer 160_O may be a negative material.

The openings OP3A may be formed on the first insulating layer 120 to be spaced apart from each other in the second direction X, and each of the openings OP3A may extend in the first direction Z. At least a part of the lower face of the redistribution patterns 150A to 150H (shown in FIG. 1) may be exposed through the openings OP3A.

Next, referring to FIGS. 16 and 29 to 32, each of UBMs 170A to 170D may be formed on the redistribution patterns 150A to 150D (S140). In other words, the UBMs 170A to 170D may be formed on redistribution layers.

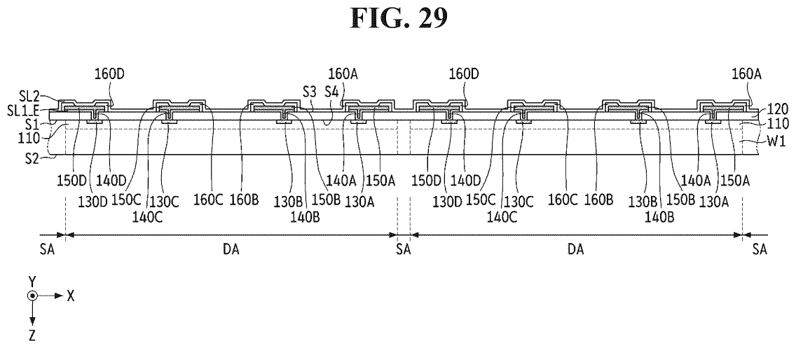

For example, referring to FIG. 29, a second seed film SL2 may be formed on the first insulating layer 120, the plurality of sub-insulating patterns 160A to 160D, and the redistribution patterns 150A to 150D. In other words, the second seed film SL2 may be deposited over the entire surface of the first insulating layer 120, the sub-insulating patterns 160A to 160D, and the redistribution patterns 150A to 150D. The second seed film SL2 may be formed through a physical vapor deposition process, but is not limited thereto.

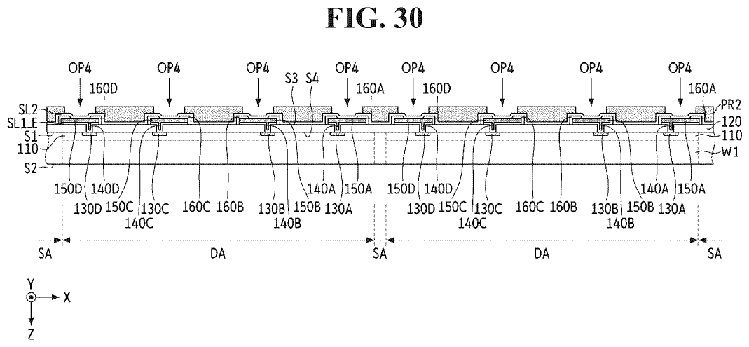

Next, referring to FIG. 30, a photoresist pattern PR2 including openings OP4 may be formed on the first insulating layer 120. At this time, the openings OP4 in the photoresist pattern PR2 may be formed by first applying a photoresist layer to the face S3 of the first insulating layer 120 using a spin coating method. This is followed by an exposure and development process using a mask. In other words, the openings OP4 of the photoresist pattern PR2 may be formed by a mask pattern. The photoresist pattern PR2 may be formed to include openings OP4 that have a width larger than the openings OP2A (shown in FIG. 28) in the regions corresponding to the openings OP2A.

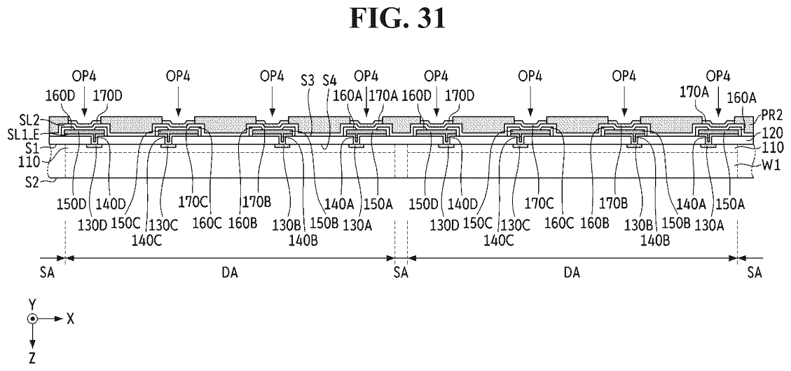

Referring next to FIG. 31, each of the UBMs 170A to 170D may then be formed in the openings OP4 by a metal plating method. At this time, each of the UBMs 170A to 170D may fill the openings OP4 of the photoresist pattern PR2. For example, the UBMs 170A to 170D may be formed through an electroless plating or electrolytic plating process. However, in the present disclosure, the method of forming the UBMs 170A to 170D is not limited thereto, and the UBMs 170A to 170D may also be formed by forming a metal layer and patterning the metal layer through an etching process.

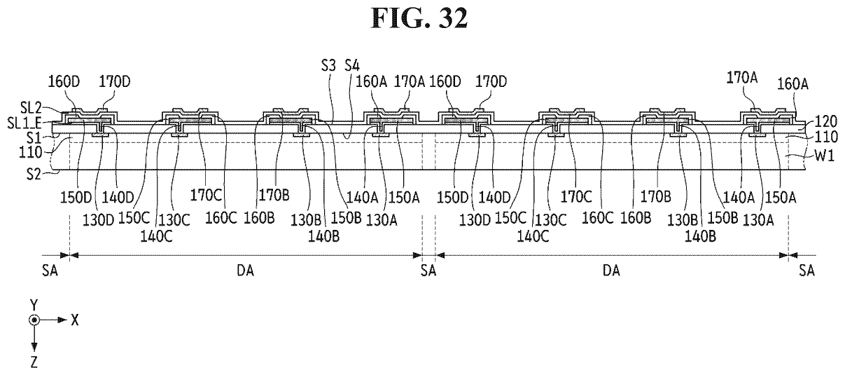

Next, referring to FIG. 32, the photoresist pattern PR2 may be removed. The photoresist pattern PR2 may be removed by dry or wet etching.

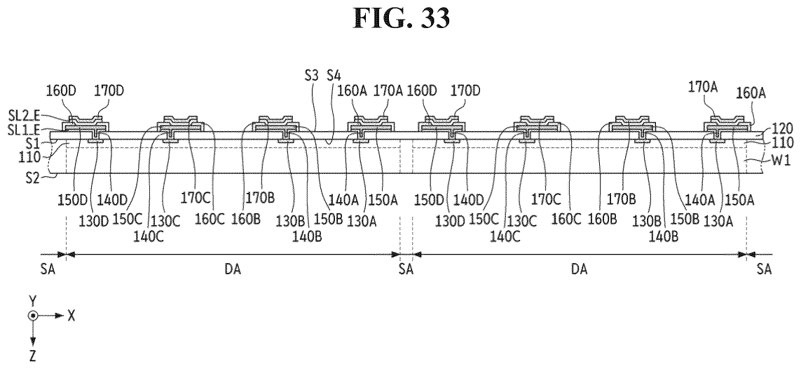

Next, referring to FIG. 33, the second seed film SL2 may be etched to form a UBM seed layer SL2_E. The UBM seed layer SL2_E may be positioned between each of the UBMs 170A to 170D and the corresponding sub-insulating patterns 160A to 160D, as well as between each of the UBMs 170A to 170D and the corresponding redistribution patterns 150A to 150D. At least a portion of the second seed film SL2 covering the lower faces of the sub-insulating patterns 160A to 160D may be removed through an etching process. Additionally, the second seed film SL2 covering the face S3 of the first insulating layer 120 may also be removed through etching.

Next, referring to FIGS. 16, 34, and 35, each of solder bumps 180A to 180H may be formed on the UBMs 170A to 170D (S150).

Solder balls 181 are provided on each of UBMs 170A to 170D, and each of solder bumps 180A to 180D may be formed. The solder bumps 180A to 180D may be formed on the UBMs 170A to 170D provided with flux, by the use of a ball drop process using ball attachment devices 500 and 510. The ball attachment devices 500 and 510 that form the conductive solder bumps 180A to 180D on the UBMs 170A to 170D may include an eject pin 500 that carries solder balls 181, and an attachment plate 510 that is formed with a plurality of holes having a width larger than that of the solder balls 181.

The wafer level package on which the UBMs 170A to 170D are formed is disposed on the attachment plate 510, and the plurality of holes and the UBMs 170A to 170D are aligned with each other. After the eject pin 500 picks up the solder balls 181 and transfers them onto the holes, the eject pin 500 may release the pickup of the solder balls 181 and drop them onto the UBMs 170A to 170D aligned below the solder balls 181. The solder balls 181 may be heated to above their melting point and reflowed, thereby forming the solder bumps 180A to 180D. While the balls 181 are melted, the solder bumps 180A to 180D that completely cover the surfaces of the UBMs 170A to 170D may be formed.

After that, the wafer level package, with the solder bumps 180A to 180D formed on the UBMs 170A to 170D, is singulated into individual semiconductor packages, thereby completing the semiconductor package 1000 shown in FIG. 1.

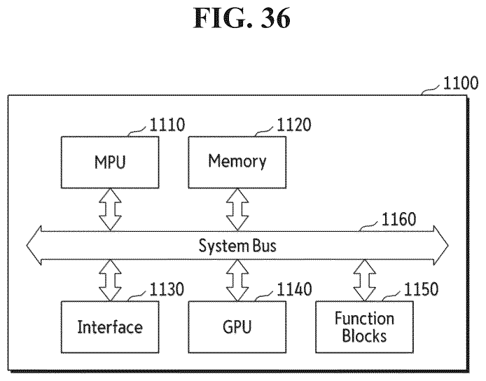

FIG. 36 is a diagram for explaining the configuration of a semiconductor package according to some embodiments.

Referring to FIG. 36, a semiconductor package 1100 may include a micro processing unit 1110, a memory 1120, an interface 1130, a graphic processing unit 1140, function blocks 1150, and a bus 1160 for connecting them. The semiconductor package 1100 may include both the micro processing unit 1110 and the graphic processing unit 1140, or may include only one of them.

The micro processing unit 1110 may include a core and an L2 cache. For example, the micro processing unit 1110 may include multi-cores. Each core of the multi-cores may have the same or different performance. Furthermore, each core of the multi-cores may be activated simultaneously or at different times from each other. The memory 1120 may store the results of processing in the function blocks 1150 under the control of the micro processing unit 1110. For example, the micro processing unit 1110 may store the contents stored in the L2 cache in the memory 1120 as they are flushed. The interface 1130 may perform an interface with external devices. For example, the interface 1130 may perform an interface with a camera, an LCD, a speaker, etc.

The graphic processing unit 1140 may perform graphics functions. For example, the graphic processing unit 1140 may perform a video codec or process 3D graphics.

The function blocks 1150 may perform various functions. For example, if the semiconductor package 1100 is an AP used in a mobile device, some of the function blocks 1150 may perform a communication function.

The semiconductor package 1100 may be any one of the semiconductor packages 1000, 1000A, 1000B, and 1000C described with reference to FIGS. 1 to 6.

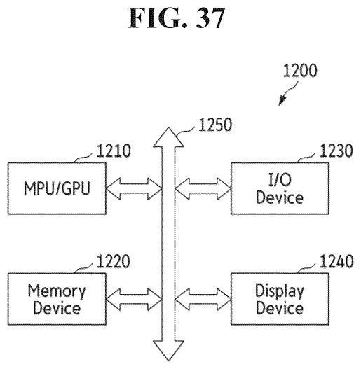

FIG. 37 is a diagram for explaining an electronic system including a semiconductor package according to some embodiments.

Referring to FIG. 37, an MPU/GPU 1210 may be mounted on an electronic system 1200. The electronic system 1200 may be, for example, a mobile device, a desktop computer or a server. Furthermore, the electronic system 1200 may further include a memory device 1220, an input/output device 1230, and a display device 1240, and each of these components may be electrically connected to a bus 1250. The MPU/GPU 1210 and the memory device 1220 may be any one of the semiconductor packages 1000, 1000A, 1000B, and 1000C described with reference to FIGS. 1 to 6.

Although embodiments of the present disclosure have been described with reference to the accompanying drawings, the disclosure is not limited to these embodiments and may be implemented in various forms. Those skilled in the art will recognize that the present disclosure can be practiced in other specific ways without departing from its technical spirit or essential characteristics. Therefore, the described embodiments should be regarded as illustrative rather than restrictive in all respects.

What is claimed is:

1. A semiconductor package comprising:
a first semiconductor chip which includes a first face and a second face opposite to each other in a first direction;
a first insulating layer which is disposed on the first face, and includes vias connected to each connecting pad of the first semiconductor chip;
redistribution patterns which are disposed on the first insulating layer;
under bump metal layers (UBM) which are respectively disposed on the redistribution patterns;
a second insulating layer which covers a part of each of the redistribution patterns; and
solder bumps which are respectively disposed on the UBMs,
wherein the first insulating layer includes a third face and a fourth face opposite to the third face in the first direction, wherein the third face is adjacent to the first face, and
a part of the fourth face does not overlap the second insulating layer in the first direction.

2. The semiconductor package of claim 1,
wherein the second insulating layer includes a plurality of sub-insulating patterns, and
each of the plurality of sub-insulating patterns covers a part of a respective one of the redistribution patterns, and
at least a first part of the plurality of sub-insulating patterns are spaced apart from each other in a second direction intersecting the first direction.

3. The semiconductor package of claim 2,
wherein at least a second part of the plurality of sub-insulating patterns are spaced apart from each other in a third direction intersecting the first direction and the second direction.

4. The semiconductor package of claim 2,
wherein the redistribution patterns include a first redistribution pattern and a second redistribution pattern which are spaced apart from each other in the second direction,
the sub-insulating patterns include a first sub-insulating pattern corresponding to the first redistribution pattern, and a second sub-insulating pattern corresponding to the second redistribution pattern,
the first sub-insulating pattern covers an outer face of the first redistribution pattern, and the second sub-insulating pattern covers an outer face of the second redistribution pattern, and
the first sub-insulating pattern and the second sub-insulating pattern are spaced apart from each other in the second direction.

5. The semiconductor package of claim 4,
wherein the first redistribution pattern includes a fifth face and a sixth face opposite to the fifth face in the first direction, wherein the fifth face is adjacent to the first insulating layer, and
at least a part of the sixth face does not contact the first sub-insulating pattern.

6. The semiconductor package of claim 5,
wherein the UBMs include a first UBM disposed on the first redistribution pattern, and
the part of the sixth face which does not contact the first sub-insulating pattern contacts a UBM seed layer interposed between the first redistribution pattern and the first UBM.

7. The semiconductor package of claim 6,
wherein the solder bumps include a first solder bump disposed on the first UBM,
the first solder bump covers at least a part of the first sub-insulating pattern, and
the first solder bump covers an outer face of the first UBM.

8. The semiconductor package of claim 1,
wherein each of the vias connects at least a part of the connecting pads to at least a part of the redistribution patterns, and at least a part of the vias extends in the first direction.

9. The semiconductor package of claim 1,
wherein the first insulating layer includes a first end and a second end in a second direction intersecting the first direction,
the second insulating layer includes a third end and a fourth end in the second direction,
wherein a distance between the third end and the first end is shorter than a distance between the third end and the second end,
a distance between the fourth end and the second end is shorter than a distance between the fourth end and the first end,
the third end is closer to an inner side of the semiconductor chip than the first end, and
the fourth end is closer to the inner side of the semiconductor chip than the second end.

10. The semiconductor package of claim 1,
wherein the first insulating layer includes a first end and a second end in the second direction intersecting the first direction,
the second insulating layer includes a third end and a fourth end in the second direction,
a distance between the third end and the first end is shorter than a distance between the third end and the second end,
a distance between the fourth end and the second end is shorter than a distance between the fourth end and the first end,
the first end and the third end overlap each other in the first direction, and
the second end and the fourth end overlap each other in the first direction.

11. The semiconductor package of claim 1, further comprising:
a mold film which covers at least a part of the third face and an outer face of the semiconductor chip.

12. A semiconductor package comprising:
a first semiconductor chip which includes a first face and a second face opposite to each other in a first direction;
a first insulating layer which covers the first face, and includes a third face and a fourth face opposite to the third face in the first direction, wherein the third face is adjacent to the first face;
first and second redistribution patterns on the first insulating layer;
first and second under bump layers (UBM) on the first and second redistribution patterns, respectively;
first and second solder bumps on the first and second UBMs, respectively;
a first sub-insulating pattern on the fourth face and corresponding to the first redistribution pattern; and
a second sub-insulating pattern on the fourth face and corresponding to the second redistribution pattern,
wherein the first sub-insulating pattern covers at least a part of the first redistribution pattern,
the second sub-insulating pattern covers at least a part of the second redistribution pattern,
the first sub-insulating pattern and the second sub-insulating pattern are spaced apart from each other, and
a first portion of the fourth face that does not overlap the first sub-insulating pattern in the first direction, and a second portion of the fourth face that does not overlap the second sub-insulating pattern in the first direction are exposed by the first sub-insulating pattern and the second sub-insulating pattern.

13. The semiconductor package of claim 12,
wherein the first sub-insulating pattern surrounds the first redistribution pattern conforming to a shape of the first redistribution pattern, and the second sub-insulating pattern surrounds the second redistribution pattern conforming to a shape of the second redistribution pattern.

14. The semiconductor package of claim 12,
wherein the fourth face includes a first edge and a second edge extending in a second direction intersecting the first direction, and
a third edge and a fourth edge extending in a third direction intersecting the first and second directions,
the first edge and the second edge are spaced apart from each other in the third direction,
the third edge and the fourth edge are spaced apart from each other in the second direction,
the first sub-insulating pattern includes a fifth edge and a sixth edge extending in the second direction, and a seventh edge and an eighth edge extending in the third direction,
the fifth edge and the sixth edge are spaced apart from each other in the third direction,
the seventh edge and the eighth edge are spaced apart from each other in the second direction,
the fifth edge and the first edge overlap each other in the second direction in a planar view point, and
the eighth edge and the fourth edge overlap each other in the third direction in the planar view point.

15. The semiconductor package of claim 14,
wherein the second sub-insulating pattern includes a ninth edge and a tenth edge extending in the second direction, and an eleventh edge and a twelfth edge extending in the third direction,
the ninth edge and the tenth edge are spaced apart from each other in the third direction,
the eleventh edge and the twelfth edge are spaced apart from each other in the second direction, and
the twelfth edge and the fourth edge overlap each other in the third direction in the planar view point.

16. The semiconductor package of claim 15,
wherein the tenth edge and the second edge overlap each other in the second direction in the planar view point.

17. A method for manufacturing a semiconductor package, the method comprising:
providing a semiconductor wafer on which a semiconductor chip is formed, the semiconductor chip including a first face on which connecting pads are disposed, and a second face opposite to the first face in a first direction;
forming a first insulating layer which includes openings for exposing the connecting pads on the first face, and includes a third face facing the semiconductor chip, and a fourth face opposite to the third face in the first direction;
forming vias connected to the connecting pads through the openings,
simultaneously forming redistribution patterns connected to the vias on the first insulating layer;
forming a second insulating layer which covers at least a part of each of the redistribution patterns on the first insulating layer;
forming under bump metal layers (UBM) respectively corresponding to the redistribution patterns on the redistribution patterns; and
forming solder bumps respectively corresponding to the UBMs on the UBMs,
wherein at least a part of the fourth face does not overlap the second insulating layer in the first direction.

18. The method for manufacturing the semiconductor package of claim 17,
wherein the forming of the second insulating layer that covers at least a part of each of the redistribution patterns on the first insulating layer includes
preventing at least a part of a face opposite to the first semiconductor chip, among both faces of the redistribution patterns opposite to each other in the first direction, from coming into contact with the second insulating layer.

19. The method for manufacturing the semiconductor package of claim 17,
wherein the forming of the UBMs respectively corresponding to the redistribution patterns on the redistribution patterns includes
covering a portion of the face of the redistribution pattern that does not come into contact with the second insulating layer with a UBM seed layer interposed between the redistribution pattern and the UBM, for each of the redistribution patterns.

20. The method for manufacturing the semiconductor package of claim 17, further comprising:
forming a mold film that covers at least a part of the third face and an outer face of the semiconductor chip.
